(19) United States
(12) Patent Application Publication
(10) Pub. No.: US 2026/0353751 A1
(43) Pub. Date: Nov. 5, 2026

(54) SELF-ALIGNED DIFFUSION BREAK SIDEWALL CONTACT

(71) Applicant: International Business Machines Corporation, Armonk, NY (US)

(72) Inventors: Reinaldo Vega, Mahopac, NY (US); Ruilong Xie, Niskayuna, NY (US); Mahender Kumar, Clifton Park, NY (US); Nicolas Jean Loubet, GUILDERLAND, NY (US); Ravikumar Ramachandran, Pleasantville, NY (US)

(21) Appl. No.: 19/197,006

(22) Filed: May 2, 2025

(51) Int. Cl. H10D 64/23; H10D 30/00; H10D 84/83

(52) U.S. Cl. CPC H10D 64/258; H10D 30/501; H10D 64/254; H10D 84/832

(57) ABSTRACT

A semiconductor device is provided including a self-aligned backside contact structure located in a diffusion break region in which the backside contact structure electrically connects to a sidewall of a source/drain region of a transistor in at least one device region. Notably, the self-aligned backside contact structure of the present application lowers the device resistance and increases the current drive in the backside contacted transistor without capacitance penalty.

### BACKGROUND

The present application relates to semiconductor technology, and more particularly to a semiconductor device including a self-aligned backside contact structure located in a diffusion break region that separates two device regions in which the backside contact structure is in conductive contact with a sidewall of a source/drain region of a transistor in at least one device region.

Backside power delivery refers to a novel technique where power supply lines are routed on the backside of a semiconductor chip or integrated circuit (IC), rather than the traditional frontside. Backside power delivery offers several advantages, including increased logic density and improved power and performance (better signal integrity, reduced noise and improved overall chip performance). Direct backside contact is a key for scaling cell heights with backside back-end-of-line (BEOL) structures that are configured for power delivery.

### SUMMARY

A semiconductor device is provided including a self-aligned backside contact structure located in a diffusion break region in which the backside contact structure is in conductive contact with a sidewall of a source/drain region of a transistor in at least one device region. Notably, the self-aligned backside contact structure of the present application lowers the device resistance and increases the current drive in the backside contacted transistor without capacitance penalty.

In one embodiment of the present application, the semiconductor device includes a backside contact structure located within at least a portion of a diffusion break region that is located adjacent to at least a first device region, where a sidewall of the backside contact structure is in conductive contact with a sidewall of a source/drain region of a transistor located in the first device region.

In another embodiment of the present application, the semiconductor includes a backside contact structure located in at least a portion of a diffusion break region that spans across an isolation region which separates a first device region from a second device region, where a first sidewall of the backside contact structure is in conductive contact with a sidewall of a source/drain region of a transistor located in the first device region and a second sidewall of backside contact structure is in conductive contact with a sidewall of a source/drain region of a transistor located in the second device region.

### BRIEF DESCRIPTION OF THE DRAWINGS

FIG. 1 is a cross-sectional view of an exemplary semiconductor device in accordance with an embodiment of the present application.

FIG. 2 is a cross-sectional view of an exemplary semiconductor device in accordance with another embodiment of the present application.

FIG. 3A is a cross-sectional view of an exemplary structure that can be employed in the present application, the exemplary structure including a nanosheet transistor located between a pair of diffusion break structures and including a gate structure wrapped around a vertical stack of spaced apart semiconductor channel material nanosheets and a pair of source/drain regions (i.e., a first source/drain region and a second source/drain region) extending partially into a semiconductor substrate.

FIG. 3B is a top-down view of the exemplary structure illustrated in FIG. 3A.

FIG. 4A is a cross-sectional view of the exemplary structure of FIG. 3A after thinning the semiconductor substrate to reveal a surface of the pair of diffusion break structures.

FIG. 4B is a top-down view of the exemplary structure illustrated in FIG. 4A.

FIG. 5A is a cross-sectional view of the exemplary structure of FIG. 4A after forming a patterned mask on the backside of the semiconductor substrate, and then selectively removing at least a portion of each diffusion break structure of the pair of diffusion break structures using the patterned mask as an etch mask to provide a pair of backside contact openings.

FIG. 5B is a top-down view of the exemplary structure illustrated in FIG. 5A.

FIG. 6A is a cross-sectional view of the exemplary structure of FIG. 5A after expanding the width of each backside contact opening to physically expose a sidewall of the first source/drain region, removing the patterned mask and forming a metal semiconductor alloy contact liner in each of the backside contact openings of the pair of backside contact openings.

FIG. 6B is a top-down view of the exemplary structure illustrated in FIG. 6A.

FIG. 7A is a cross-sectional view of the exemplary structure of FIG. 6A after forming a backside contact structure in each of the expanded width backside contact openings of the pair of backside contact openings and in contact with the metal semiconductor alloy contact liner that is also present in the expanded width backside contact opening.

FIG. 7B is a top-down view of the exemplary structure illustrated in FIG. 7A.

FIG. 8A is a cross-sectional view of the exemplary structure of FIG. 7A after backside metallization and forming a backside back-end-of-line (BEOL) structure.

FIG. 8B is a top-down view of the exemplary structure illustrated in FIG. 8A.

FIG. 9 is a cross-sectional view of a semiconductor device in accordance with another embodiment of the present application.

FIG. 10 is a cross-sectional view of a semiconductor device in accordance with a further embodiment of the present application.

FIG. 11 is a cross-sectional view of a semiconductor device in accordance with an even further embodiment of the present application.

FIG. 12 is a cross-sectional view of a semiconductor device in accordance with a still further embodiment of the present application.

FIG. 13 is a top-down view of a semiconductor device in accordance with yet a further embodiment of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Direct backside contact is a key for scaling cell heights with backside BEOL structures that are configured for power delivery. Self-aligned direct backside contact is difficult to achieve without adding complexity. Brute-force direct backside contact alignment avoids structural complexity, but adds cost to the overall manufacturing process. The present application discloses a semiconductor device including a self-aligned backside contact to a source/drain region of a transistor. The self-aligned backside contact of the present application has low resistance and does not have a capacitance penalty as is the case with most direct backside contact structures.

A transistor (or field effect transistor (FET)) includes a source region, a drain region, a semiconductor channel region located between the source region and the drain region, and a gate structure in contact with the semiconductor channel region. Collectively, the source region and the drain region can be referred to as a source/drain region. As used herein, a “source/drain” region can be a source region or a drain region depending on subsequent wiring and application of voltages during operation of the transistor. In the embodiment described in the present application, the transistor is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology. Although nanosheet transistors are described in this application, this application is not limited to nanosheet transistors. Instead, the present application can be used for finFETs, nanowire FETs, planar FETs, fork sheet transistors, stacked FETs or any combination of such FETs including nanosheet transistors.

In the present application, the semiconductor device includes a frontside and a backside. The frontside includes a side of the device that includes at least one transistor, a frontside contact structure, and a frontside BEOL structure. The backside of the semiconductor device is the side of the device that is opposite the frontside. The backside includes backside contact structures, and a backside BEOL structure. The backside BEOL structure can be a backside power distribution network that is capable of delivering power to the transistor through the backside of the semiconductor device.

Throughout the present application, a device region denotes an active region (or active area) in which one or more transistors such as, for example, nanosheet transistors can be formed. In the present application, a plurality of device regions such as, for example, a first device region, A1, and a second device region, A2, can be present. In some embodiments, the first device region, A1, and the second device region, A2, are present in different rows from each other. In such embodiments, an isolation region can be located between the different device regions. In the present application, the isolation region runs parallel to a length-wise direction of the first device region, A1, and the second device region, A2. In other embodiments, the first device region, A1, and the second device region, A2, are present in a row. In the present application, a diffusion break structure can be located adjacent to one device region and can span from one device region to another device region and pass across the isolation region. In the present application, the diffusion break structure is an electrical isolation structure that runs perpendicular and into each of the device regions.

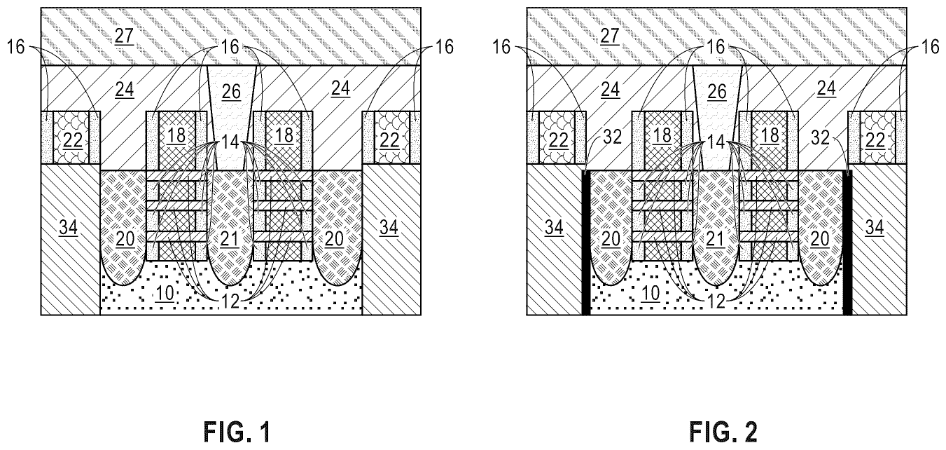

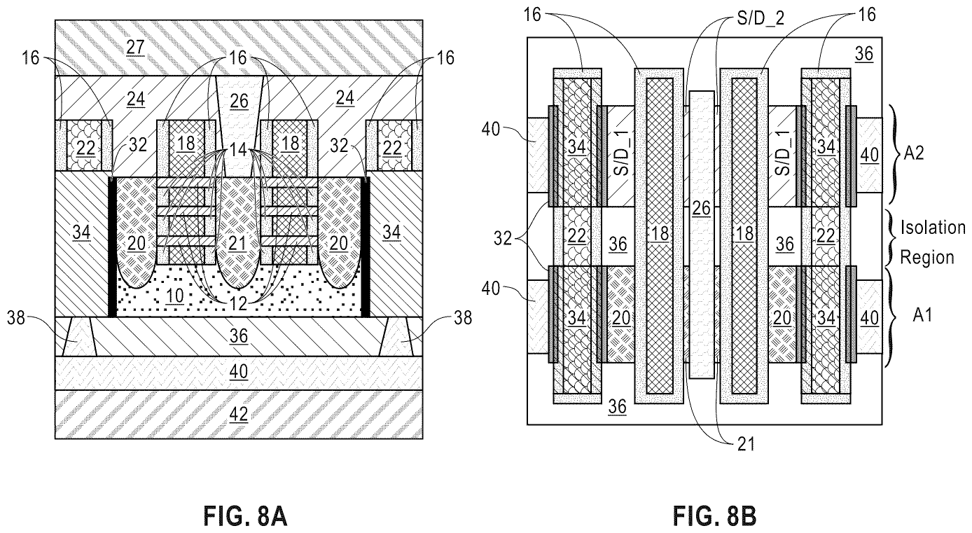

Notably, and in one embodiment of the present application (see, for example, FIGS. 1, 8A and 8B), the semiconductor device includes a backside contact structure 34 located within at least a portion of a diffusion break region (i.e., a region that includes or previously included diffusion break structure 22) that is present adjacent to a first device region, A1 (i.e., the region illustrated from the left to right in FIGS. 1 and 8A), where a sidewall of the backside contact structure 34 is in conductive contact with a sidewall of a source/drain region (e.g., first source/drain region 20) of a transistor that is present in the first device region, A1. The backside contact structure 34 of the present application lowers the device resistance and increases the current drive in the backside contacted transistor without capacitance penalty. The backside contact structure 34 of the present application is self-aligned to diffusion break structure 22.

In the embodiment illustrated in FIG. 1, the sidewall of the backside contact structure 34 is in direct physical contact with a sidewall of the source/drain region of the transistor present in the first device region, A1. Such contact can result in an increase in contact area between the backside contact structure 34 and the source/drain region, thus reducing external resistance and increasing current drivability.

In some embodiments (see, for example, FIG. 8B), the semiconductor device can further include a second device region, A2, (in another row from the first device region, A1), separated from the first device region, A1, by an isolation region, where the diffusion break region spans across the isolation region and is adjacent to the second device region, A2. Note that in the present application, the diffusion break region is located at an end of a particular device region.

In some embodiments (see, for example, FIG. 2), the semiconductor device can include a metal semiconductor alloy contact liner 32 separating the backside contact structure 34 from the source/drain region (e.g., first source/drain region 20) of the transistor in the first device region, A1. The presence of the metal semiconductor alloy contact liner 32 (e.g., a metal silicide) provides enhanced device performance and facilitates a lower contact resistance than the case when direct physical contact between the backside contact structure 34 and the source/drain region (e.g., first source/drain region 20) of the transistor in the first device region, A1, occurs.

In some embodiments, the semiconductor device can further include a well region (as further defined below) located beneath the transistor, wherein the sidewall of backside contact structure 34 further contacts the well region; in such an embodiment, and if present, the metal semiconductor alloy contact liner 32 can be located between a sidewall of the well region and the backside contact structure 34. This result in a localized well connection. In conventional bulk CMOS, the well connection is made past the end of the circuit row. This requires the well resistance to be low enough to maintain a well potential at or near the applied well bias for devices placed far from the well contact. By having a localized well connection, the well resistance has a much smaller impact on the well potential.

In some embodiments, the semiconductor device can include a backside source/drain contact structure 44 contacting a source/drain region (e.g., first source/drain region 20) of another transistor in the first device region, A1.

In some embodiments, the semiconductor device can include backside BEOL structure 42 located beneath the transistor and in contact with the backside contact structure 34. In the present application, backside BEOL structures 42 can be configured to deliver power from the backside of the device. Backside power delivery is a robust way of power delivery and offers several advantages, including increased logic density and improved power and performance (better signal integrity, reduced noise and improved overall chip performance).

In some embodiments (see, for example, FIG. 8A), the semiconductor device can include a frontside source/drain contact structure 26 in contact with another source/drain region (e.g., second source/drain region 21) of the transistor in the first device region, A1.

In some embodiments (see, for example, FIG. 8A), the semiconductor device can include a frontside BEOL structure 27 in contact with the frontside source/drain contact structure 26.

In some embodiments (see, for example, FIG. 10 (Region 1), the semiconductor device further includes another backside contact structure (e.g., backside contact structure 34 in Region 11) having a sidewall that is in conductive contact with a sidewall of a source/drain region (e.g., first source/drain region 20) of a transistor located in the second device region, A2, where the backside contact structure and the another backside contact structure are located within the diffusion break region and are spaced apart by a least a portion of a portion of the diffusion break region.

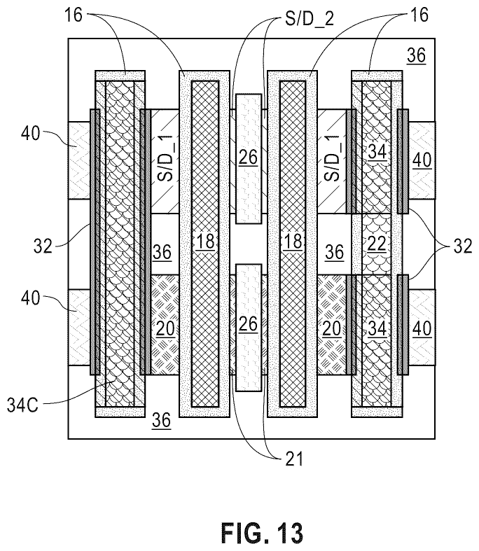

In some embodiments (see, for example, FIG. 13), the backside contact structure 34 extends across the isolation region and through at least a portion of the diffusion break region and contacts a sidewall of a source/drain region (i.e., S/D_1) of a transistor in the second device region, A2. This is beneficial when source/drain regions from the first and second device regions share a connection. For example, the first and second device regions may both include NFETs and source/drain regions from each may share a connection to ground, or they may be PFETs which share a connection to VDD, or they may be one NFET and one PFET which share a signal output connection.

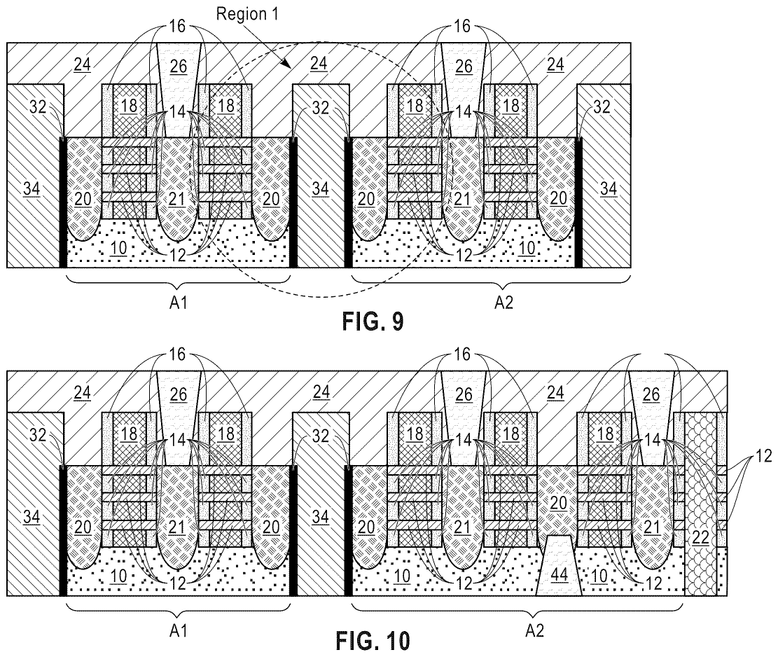

In another embodiment of the present application (see, for example, FIGS. 9-12), the semiconductor includes a backside contact structure 34 located in at least a portion of a diffusion break region (i.e., a region that includes or previously included diffusion break structure 22) that spans across an isolation region which separates a first device region, A1, from a second device region, A2, where a first sidewall of the backside contact structure 34 (see, for example, Region 1 shown in FIG. 8) is in conductive contact with a sidewall of a source/drain region (e.g., first source/drain region 20) of a transistor located in the first device region, A1, and a second sidewall of the backside contact structure 34 is in conductive contact with a sidewall of a source/drain region (e.g., first source/drain region 20) of a transistor located the second device region, A2. The backside contact structure 34 of the present application lowers the device resistance and increases the current drive in the backside contacted transistor without capacitance penalty. The backside contact structure 34 of the present application is self-aligned to diffusion break structure 22.

In some embodiments, the first sidewall of the backside contact structure 34 directly contacts the sidewall of the source/drain region (e.g., first source/drain region 20) of the transistor in the first device region, A1, and the second sidewall of the backside contact structure 34 directly contacts the sidewall of the source/drain region (e.g., first source/drain region 20) of the transistor in the second device region, A2.

In some embodiments (see, for example, FIGS. 9-12), the semiconductor device can include a metal semiconductor alloy contact liner 32 separating the backside contact structure 34 from the source/drain region (e.g., first source/drain region 20) of the transistor in the first device region, A1, and the source/drain region (e.g., first source/drain region 20) of the transistor in the second device region, A2. The presence of the metal semiconductor alloy contact liner 32 (e.g., a metal silicide) provides enhanced device performance as mentioned above.

In some embodiments, the semiconductor device can include a well region located beneath the transistors, wherein the first sidewall and the second sidewall of the backside contact structure 34 further contact the well region.

In some embodiments, the semiconductor device can include a backside BEOL structure 42 located beneath the transistor located in the first device region and the transistor located in the second device region, where the backside BEOL structure 42 is in contact with the backside contact structure 34. Backside BEOL structure 42 can deliver backside power to the device providing the advantages already mentioned herein to the device.

In some embodiments, the semiconductor device can include frontside source/drain contact structure 26 in contact with another source/drain region (e.g., second source/drain region 21) of the transistor located in the first device region, A1, and another frontside source/drain contact structure (26) in contact with another source/drain region (e.g., second source/drain region 21) of the transistor located in the second device region, A2.

In some embodiments, the semiconductor device can include a frontside BEOL structure 27 in contact with each frontside source/drain contact structure.

In some embodiments, the semiconductor device can include a backside source/drain contact structure 44 contacting a source/drain region (e.g., first source/drain region 20) of another transistor located in the second device region, A2. This is the case when multiple power connections are required within the cell. If the cell is bordered on each side (in the length direction) by diffusion break structures and has diffusion break contacts in those regions, then one can allow for two power connections through those diffusion break contacts. However, if a third (or fourth, etc.) power connection is required (for example, for a 3-input NAND gate), then an additional backside contact is necessary to enable this connection.

In some embodiments, the semiconductor device can include a frontside contact structure 25 contacting the backside contact structure 34. This permits using the diffusion break contact structure as if it were a through-silicon-via (TSV), where either of power or signal connections can be routed from the frontside to the backside.

In some embodiments including the frontside contact structure 25, the semiconductor device further includes backside source/drain contact structure 44 contacting a source/drain region (e.g., first source/drain region 20) of another transistor located in the second device region, A2.

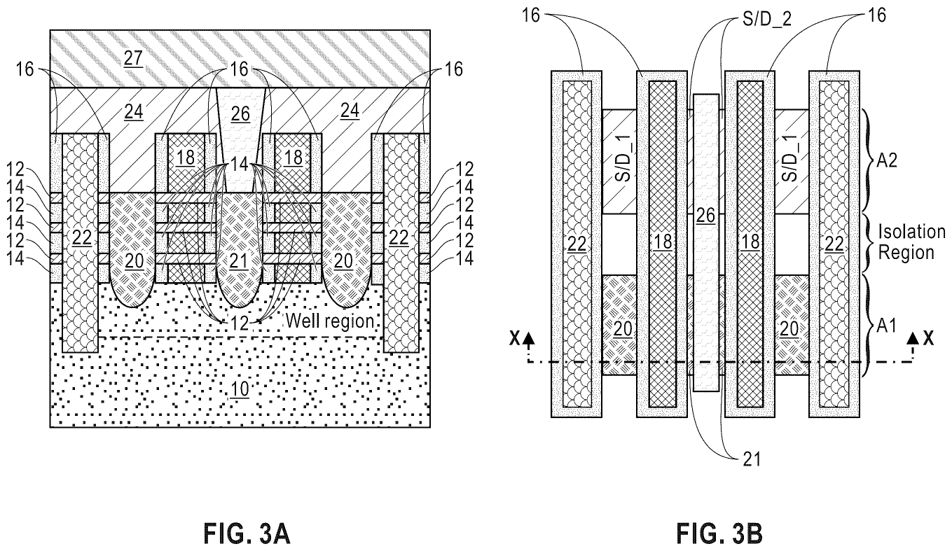

Referring now to FIGS. 3A-3B, there are illustrated an exemplary structure that can be employed in the present application in forming a semiconductor device in accordance with the present application. It is noted that FIG. 3B is a top-down view of the exemplary minus the frontside BEOL structure 27 illustrated in FIG. 3A. FIG. 3A is a cross sectional view along X-X which is located in a first device region, A1 as shown in FIG. 3B; FIG. 3B also includes a second device region, A2. The second device region, A2, is spaced apart from the first device region, A1, by an isolation region (See, FIG. 3A). The first device region, A1, is an active device area in which a first conductivity transistor (i.e., nFET or pFET) can be formed, while the second device region, A2, is an active device area in which a second conductivity type transistor (of the same or opposite conductivity type than the first conductivity transistor) can be formed. For this example, the transistor in the second device region, A2, includes first source/drain region, SD_1 and second source/drain region, SD_2, as illustrated in FIG. 3A. In the illustrated embodiment, the first device region, A1, is present in a first row, and the second device region is present in a second row, which is different from the first row; an isolation region separates A1 from A2.

The exemplary structure includes a nanosheet transistor (two of which are illustrated in the drawings by way of one example) located between a pair of diffusion break structures 22. Although a pair of diffusion break structures 22 are shown, the present application works when a single diffusion structure or more than two diffusion break structures are employed. The nanosheet transistor includes a gate structure 18 wrapped around a vertical stack of spaced apart semiconductor channel material nanosheets and a pair of source/drain regions (i.e., a first source/drain region 20 and a second source/drain region 21) extending partially into a semiconductor substrate 10. Each vertical stack of spaced apart semiconductor channel material nanosheets includes a plurality of semiconductor channel material nanosheets 12. In the present application, the first source/drain region 20 is located on a first side of the gate structure 18 and the second source/drain region 21 is located on a second side of the gate structure 18, the second side of the gate structure 18 is opposite the first side of the gate structure 18. The exemplary structure illustrated in FIG. 3A further includes a frontside BEOL structure 27 in contact with the second source/drain region 21 of the transistor by a frontside source/drain contact structure 26. The frontside source/drain contact structure 26 is embedded in a multilayered frontside ILD structure 24. Collectively, the multilayered frontside ILD structure 24 and the frontside source/drain contact structure 26 provide a middle-of-line (MOL) level.

For the nanosheet transistor embodiment illustrated in the present application, the exemplary structure can also include gate spacer 16 and inner spacers 14. The gate spacer 16 is located along a sidewall of the gate structure 18 and inner spacers 14 are located beneath and at each of the ends of the semiconductor channel material nanosheets 12.

Each of the various components illustrated in FIGS. 3A-3B are now described in greater detail. The semiconductor substrate 10 includes at least a semiconductor device layer. The semiconductor device layer is an uppermost portion of the semiconductor substrate 10 in which a transistor will be formed thereon. The semiconductor substrate 10 can also include a semiconductor base layer and/or an etch stop layer. In one example, the semiconductor substrate 10 can include, from bottom to top, a semiconductor base layer, an etch stop layer and a semiconductor device layer. The semiconductor base layer of the semiconductor substrate 10 is composed of a first semiconductor material, and the semiconductor device layer of the semiconductor substrate 10 is composed of a second semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor device layer can be compositionally the same as, or compositionally different from, the first semiconductor material that provides the semiconductor base layer. In some embodiments of the present application, the etch stop layer of the semiconductor substrate 10 can be composed of a dielectric material such as, for example, silicon dioxide and/or boron nitride. In other embodiments of the present application, the etch stop layer of the semiconductor substrate 10 is composed of a third semiconductor material that is compositionally different from the first semiconductor material that provides the semiconductor base layer and the second semiconductor material that provides the semiconductor device layer. In one example, the semiconductor base layer is composed of Si, the etch stop layer is composed of silicon dioxide, and the semiconductor device layer is composed of Si. In another example, the semiconductor base layer is composed of Si, the etch stop layer is composed of SiGe, and the semiconductor device layer is composed of Si.

In embodiments of the present application, the semiconductor device layer of the semiconductor substrate 10 can contain a well region (i.e., p-type well region or an n-type well region). The p-type well region is employed in embodiments in which the transistor is an nFET, while the n-type well region is employed in embodiments in which the transistor is a pFET. A p-type well region includes a p-type dopant, while an n-well region includes an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor.

Each semiconductor channel material nanosheet 12 of the vertical stack of spaced apart semiconductor channel material nanosheets includes a fourth semiconductor material. The fourth semiconductor material can be compositionally the same as, or compositionally different from, the second semiconductor material that provides the semiconductor device layer of the semiconductor substrate 10. In some embodiments, the fourth semiconductor material that provides each semiconductor channel material nanosheet 12 provides high channel mobility for nFET devices. In other embodiments, the fourth semiconductor material that provides each semiconductor channel material nanosheet 12 provides high channel mobility for pFET devices. In one example, each semiconductor channel material nanosheet 12 is composed of Si. The number of semiconductor channel material nanosheets 12 present in each vertical stack of semiconductor channel material nanosheets 12 can vary and is not limited to three as exemplified in FIG. 3A.

The gate spacer 16 and the inner spacer 14 are composed of a compositionally same or different spacer dielectric material. The dielectric spacer material can include, but is not limited to, silicon dioxide, SiN, SiBCN, SiOCN or SiOC.

The gate structure 18 includes a gate dielectric material and a gate electrode, both of which are not separately shown, but intended to be within the region defined by gate structure 18. As is known to those skilled in the art, a gate dielectric material directly contacts a physically exposed surface(s) of the semiconductor channel region, and a gate electrode is formed on the gate dielectric material. The gate dielectric material has a dielectric constant of 4.0 or greater. All dielectric constants mentioned herein are measured in a vacuum unless stated to the contrary. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc, Ta)O₃), and/or lead zinc niobite (Pb(Zn, Nb)O). The gate dielectric material can further include dopants such as lanthanum (La), aluminum (Al) and/or magnesium (Mg). The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co).

Each source/drain region (including the first source/drain region 20 and the second source/drain region 21) extends outward from a sidewall of the semiconductor channel material nanosheets 12 of a given vertical stack of semiconductor channel material nanosheets 12. Each source/drain region is composed of a fifth semiconductor material and a dopant. As used herein, a “source/drain” region can be a source region or a drain region depending on subsequent wiring and application of voltages during operation of the transistor. The fifth semiconductor material that provides the first source/drain region 20 and the second source/drain region 21 can be compositionally the same as, or compositionally different from, the fourth semiconductor material that provides each semiconductor channel material nanosheet 12. The dopant that is present in the first source/drain region 20 and the second source/drain region 21 can be either a p-type dopant or an n-type dopant. In a silicon containing semiconductor material, examples of n-type dopants, i.e., impurities, include, but are not limited to, antimony, arsenic and phosphorous. In one example, each source/drain region can have a dopant concentration of from 4×10²⁰ atoms/cm³ to 3×10²¹ atoms/cm³. As is shown, each source/drain region including the first source/drain region 20 and the second source/drain region 21 extends beneath a topmost surface of the semiconductor substrate 10 and has a bottommost surface that is located in a sub-surface of the semiconductor substrate 10. The term “sub-surface” is used throughout the present application to denote a surface of a layer/structure that is located between a topmost surface and a bottommost surface of the layer/structure. In the present application, the depth of the first source/drain region 20 and the second source/drain region 21 in the semiconductor substrate 10 is less than a depth of each diffusion break structure 22.

Each diffusion break structure 22 is composed of at least one trench dielectric material. An example of a trench dielectric material that can be used in providing the diffusion break structure 22 is silicon oxide. The diffusion break structure 22 can be referred to as a frontside dielectric structure or a frontside isolation structure. Each diffusion break structure 22 is formed between the gate spacer 16 and the inner spacers 14, passes through a middle portion of a vertical stack of spaced apart semiconductor channel material nanosheets and lands on a sub-surface of semiconductor substrate 10. Each diffusion break structure 22 has a depth in the semiconductor substrate 10 that is greater than a depth of the source/drain regions in the semiconductor substrate 10. Each diffusion break structure 22 can be formed by lithography and etching a trench that extends into the semiconductor substrate 10. The trench is then filled with a trench dielectric material. The filling of the trench can include deposition, followed by planarization. Each diffusion break structure 22 is used to electrically isolate at least one transistor from another transistor. The diffusion break structure 22 can be used to reduce the distance between active device areas and enable area-scaling.

The multilayered frontside ILD structure 24 includes two frontside ILD layers; the first frontside ILD layer represents a lower portion of the multilayered frontside ILD structure 24, while the second frontside ILD layer represent an upper portion of the multilayered frontside ILD structure 24. The first frontside ILD layer is composed of a first ILD material, while the second frontside ILD layer is composed of a second ILD material. The second ILD material can be compositionally the same as, or compositionally different from, the first ILD material. An ILD material is a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0.

The frontside source/drain contact structure 26 is composed of at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The frontside source/drain contact structure 26 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above.

The frontside BEOL structure 27 is composed of an interconnect dielectric region having frontside metal wiring embedded therein; the frontside metal wiring present in the frontside BEOL structure 27 is typically signal wires. The interconnect dielectric region includes one or more interconnect dielectric material layers. The interconnect dielectric material layers can be composed of at least one of the ILD materials mentioned above. The frontside metal wiring can be in the form of metal lines, metal vias, metal via/metal line combinations or any combination thereof. The frontside metal wiring is composed of an electrically conductive metal or an electrically conductive metal alloy. Exemplary electrically conductive metals include, but are not limited to, Cu, W, Al, Co, or Ru. An exemplary electrically conductive metal alloy is a Cu—Al alloy.

Carrier wafer (not shown) can be present on top of the frontside BEOL structure 27. The carrier wafer can include a semiconductor material as exemplified above. Carrier wafer is bonded to the frontside BEOL structure 27 by a bonding dielectric layer (not shown). Illustrative examples of dielectric materials that are used as the bonding dielectric layer include, but are not limited to, tetraethyl orthosilicate (TEOS), SiO₂, silicon carbon nitride (SiCN) and/or carbon-doped silicon oxide (SiCOH).

The exemplary structure shown in FIGS. 3A-3B can be formed utilizing any well-known nanosheet transistor device fabrication process. The nanosheet transistor device fabrication process typically includes the use of a sacrificial gate structure which is used in defining a nanosheet stack of alternating sacrificial semiconductor nanosheets and semiconductor channel material nanosheets. After defining the nanosheet stack, the sacrificial gate structure is removed to reveal the underlying nanosheet stack and thereafter each sacrificial semiconductor material nanosheet of the nanosheet stack is removed and thereafter a gate structure is formed wrapping around each of the suspended semiconductor channel material nanosheets of the nanosheet stack.

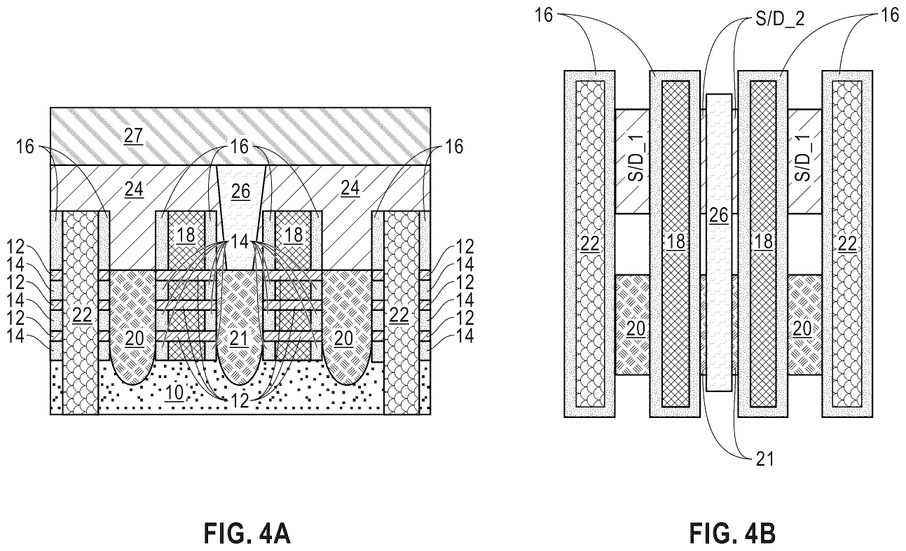

Referring now to FIGS. 4A-4B, there are shown the exemplary structure of FIGS. 3A-3B, respectively, after thinning the semiconductor substrate 10 to reveal a surface of each diffusion break structure 22. Prior to thinning the semiconductor substrate 10, the exemplary structure illustrated in FIGS. 3A-3B is flipped 180° to physically expose a backside of the exemplary structure. For clarity, the flipping step is not shown in the drawings of the present application. Flipping can be performed by hand or by utilizing a mechanical means such as, for example, a robot arm. After flipping, the semiconductor substrate 10 is thinned utilizing one or more material removal processes that is/are selective in removing a portion of the semiconductor substrate 10. The one or more material process can include an etching process, a planarization process such as, for example, chemical mechanical planarization (CMP) or a combination of etching and planarization. In embodiments, the semiconductor base layer and the etch stop layer are removed, and then the semiconductor device layer is thinned. Note that since the first source/drain region 20 and the second source/drain region 21 have a shallower depth in the semiconductor substrate 10, a portion (i.e., semiconductor device layer) of the semiconductor substrate 10 remains beneath each of the first source/drain region 20 and the second source/drain region 21. The remaining portion of the semiconductor substrate can include a well region as defined above.

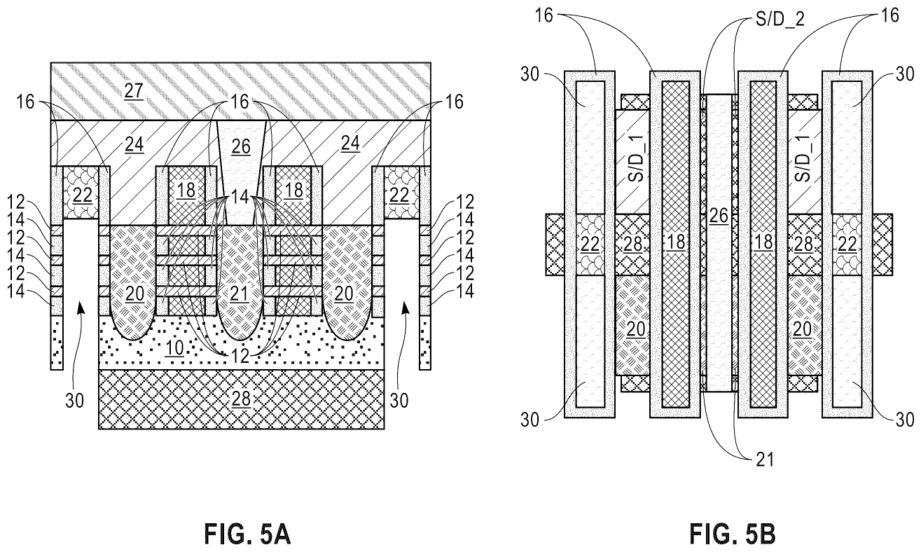

Referring now to FIGS. 5A-5B, there are shown the exemplary structure of FIGS. 4A-4B, respectively, after forming a patterned mask 28 on the backside of the semiconductor substrate 10, and then selectively removing at least a portion of each diffusion break structure 22 of the pair of diffusion break structures using the patterned mask 28 as an etch mask to provide a pair of backside contact openings 30. In some embodiments (not shown in FIGS. 5A-5B), the entirety of each of each diffusion break structure 22 of the pair of diffusion break structures can be removed.

In some embodiments, the patterned mask 28 is composed of a dielectric hard mask material such as, for example, silicon nitride, silicon oxide, silicon oxynitride or any multilayered stack thereof. In embodiments in which the patterned mask 28 is composed of a dielectric hard mask material, the patterned mask 28 can be formed by depositing a layer of dielectric hard mask material on remaining semiconductor substrate 10. The depositing of the layer of dielectric hard mask material includes, for example, chemical vapor deposition (CVD), plasma enhanced chemical vapor deposition (PECVD), physical vapor deposition (PVD) or atomic layer deposition (ALD). After depositing of the layer of dielectric hard mask material, the as-deposited layer of dielectric hard mask material is patterned by lithography and etching. Lithography includes depositing a photoresist material on a layer/structure that needs to be patterned, then exposing the as-deposited photoresist material to a desired pattern of irradiation and thereafter developing the exposed photoresist material to provide a patterned photoresist material on the layer/structure that needs to be patterned. An etch including a dry etching process and/or a chemical wet etching process is then used to transfer the patterned from the patterned photoresist material into the underlying layer/structure. Dry etching can include, for example, reactive ion etching (RIE), plasma etching or ion beam etching (IBE). Chemical wet etching includes the use of a chemical etchant that is selective in removing one material as compared to another material. The patterned photoresist material is removed after transferring the pattern into the underlying layer/structure utilizing a conventional resist removal process such as, for example, ashing. In other embodiments, the patterned mask 28 can be composed of a photoresist material. In embodiments in which the patterned mask 28 is composed of a photoresist material, the patterned mask can be formed by utilizing lithography as defined above.

In either embodiment, the patterned mask 28 is formed on the semiconductor substrate 10 in an area that is located between the pair of diffusion break structures 22. The patterned mask 28 is designed to have an outermost sidewall that is substantially vertically aligned to an outermost sidewall of the first source/drain region 20. In some embodiments, only one of the diffusion break structures 22 is removed. In other embodiments, a plurality of diffusion break structures 22 are removed.

With the patterned mask 28 in place, an etching process such as, for example, RIE, can be used to selectively remove at least a portion of each diffusion break structure 22 of the pair of diffusion break structures. In the illustrated embodiment, each backside contact opening 30 extends from the backside of semiconductor substrate 10 to a remaining position of one of the diffusion break structures 22. In other embodiments (not illustrated in FIGS. 5A-5B), each backside contact opening 30 extends from the backside of semiconductor substrate 10 to a surface of the multilayered frontside ILD structure 24.

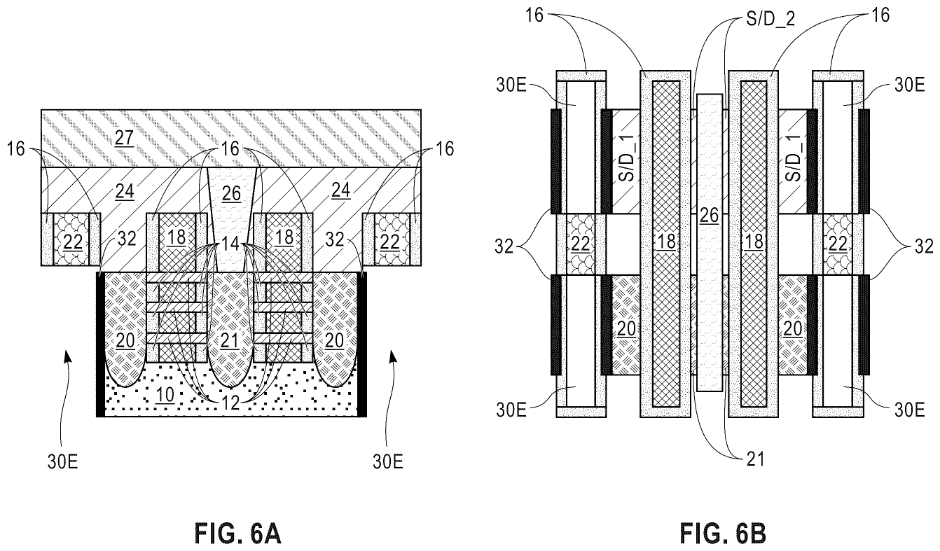

Referring now to FIGS. 6A-6B, there is shown the exemplary structure of FIGS. 5A-5B, respectively, after expanding the width of each backside contact opening 30 to physically expose a sidewall of the first source/drain region 20, removing the patterned mask 28 and forming a metal semiconductor alloy contact liner 32 in each of the backside contact openings 30 of the pair of backside contact openings. The expanding of the width of each backside contact opening 30 provides expanded width backside contact opening 30E as illustrated in FIG. 6A. In some embodiments, the expanding the width of each backside contact opening 30 includes a selective inner spacer and semiconductor material etch that removes physically exposed portions of the semiconductor substrate 10, semiconductor channel material nanosheets 12 and inner spacers 14 within the backside contact opening 30 such that a sidewall of the first source/drain region 20 is physically exposed. Backside contact opening 30 provides the expanded width backside contact opening 30E as illustrated in FIG. 6A. In other embodiments, the expanding the width of each backside contact opening 30 includes a non-selective isotropic etch (such as, for example, RIE) which removes physically exposed portions of the semiconductor substrate 10, semiconductor channel material nanosheets 12 and inner spacers 14 within the backside contact opening 30 such that a sidewall of the first source/drain region 20 is physically exposed. After widening the backside contact opening 30, the patterned mask 28 can be removed from the backside of the semiconductor substrate 10 utilizing a conventional removal process that is well known to those skilled in the art.

The metal semiconductor alloy contact liner 32 is optional and does not need be formed in all embodiments of the present application. The metal semiconductor alloy contact liner 32 is generally used in embodiments in which high performance semiconductor devices are desirable. When present, the metal semiconductor alloy contact liner 32 is formed on the physically exposed sidewall of the first source/drain region 20 and the physically exposed sidewall of the semiconductor substrate 10 (i.e., along a sidewall of the semiconductor device layer that can include a well region as defined above).

The metal semiconductor alloy contact liner 32 is composed of a metal semiconductor alloy forming metal and a semiconductor material that provides the first source/drain region 20 and the semiconductor device layer of the semiconductor substrate 10. The semiconductor material that provides the first source/drain region 20 and the semiconductor device layer of the semiconductor substrate 10 can be compositionally the same or compositionally different from each other. In cases in which the semiconductor material that provides the first source/drain region 20 and the semiconductor device layer of the semiconductor substrate 10 are compositionally different, the metal semiconductor alloy contact liner 32 can include an upper portion that includes the semiconductor material that provides the first source/drain region 20 and a lower portion (along the sidewall of the physically exposed semiconductor substrate 10) that includes the semiconductor material that provides the semiconductor device layer of the semiconductor substrate 10. In some embodiments (in which the second source/drain region 21 and the semiconductor device layer of the semiconductor substrate 10 are composed of Si), the metal semiconductor alloy contact liner 32 is a metal silicide. The metal semiconductor alloy forming metal includes any metal that is capable of reacting with a semiconductor material to form a metal semiconductor alloy. Illustrative examples of metal semiconductor alloy forming metals that can be used in the present application, includes, but are not limited to, Ni, Pt, Pd, or W.

The metal semiconductor alloy contact liner 32 can be formed by forming a layer of metal semiconductor alloy forming metal within the expanded width backside contact opening 30E by a deposition process such as, for example, CVD, PVD, atomic layer deposition (ALD), or sputtering, and thereafter performing a metal semiconductor alloy forming anneal that causes reaction between the metal semiconductor alloy forming metal and the semiconductor material of both the first source/drain region 20 and the semiconductor device layer of the semiconductor substrate 10. The anneal can be performed at a temperature of 500 °C, and typically within an inert ambient.

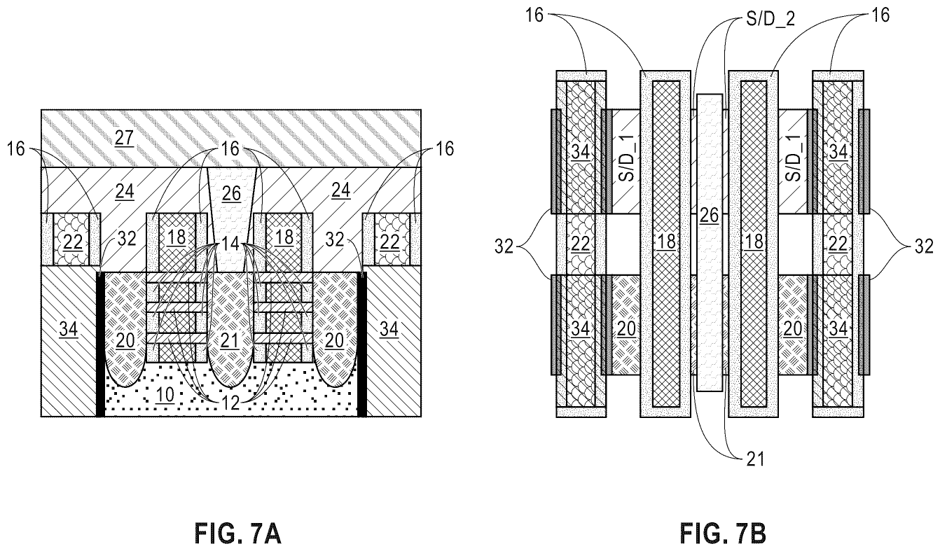

Referring now to FIGS. 7A-7B, there is shown the exemplary structure of FIGS. 6A-6B, respectively, after forming a backside contact structure 34 in each expanded width backside contact opening 30E of the pair of backside contact openings and in contact with the metal semiconductor alloy contact liner 32 that is also present in the expanded width backside contact opening 30E. In the illustrated embodiment, the backside contact structure 34 is in direct physical contact with a sidewall of the metal semiconductor alloy contact liner 32. In other embodiments (see, for example, the semiconductor device illustrated in FIG. 2), the backside contact structure 34 is in direct physical contact with a sidewall of the first source/drain region 20 and a sidewall of the semiconductor substrate 10. The backside contact structure 34 is composed of a conductive metal such as, for example, W, Cu, Al, Co, Ru, Mo, Os, Ir, Rh, or an alloy thereof. The backside contact structure 34 can be formed by deposition of the contact conductor material, followed by a planarization process. The deposition of the contact conductor material can include, for example, CVD, PECVD, ALD, sputtering or plating. A planarization process can follow the contact conductor deposition to remove any metal and metal semiconductor alloy that is formed outside of the expanded width backside contact opening.

Referring now to FIGS. 8A-8B, there is shown the exemplary structure of FIGS. 7A-7B, respectively, after backside metallization, and forming a backside BEOL structure 42. Backside metallization can include, for example, forming backside metal structures such as, for example, backside metal via 38 in a backside ILD layer 36, and backside metal line 40 in another backside ILD layer (not shown in the cross-sectional view). The backside metal via 38 and/or backside metal line 40 are optional components.

The backside ILD layer 36 and the other backside ILD layer (not shown) include one of the ILD materials mentioned above for the multilayered frontside ILD structure 24. The backside ILD layer 36 and the other backside ILD layer can be composed of a compositionally same, or compositionally different, ILD material. The backside ILD layer 36 and the other backside ILD layer can be formed by a deposition process including, for example, CVD, PECVD or spin-coating. The backside metal via 38 and the backside metal line 40 are composed of an electrically conductive metal or electrically conductive metal alloy, as both defined above. The backside metallization includes forming openings (i.e., via openings and/or line openings) within a backside ILD layer and then filling the openings with an electrically conductive metal or electrically conductive metal alloy. The filling can include deposition, followed by a planarization process. In the illustrated embodiment, the backside metal via 38 has a first surface in direct physical contact with a surface of the backside contact structure 34, and a second surface, opposite the first surface, in direct physical contact with a first surface of the backside metal line 40. The second surface of the backside metal line 40, that is opposite the first surface of the backside metal line 40 is in direct physical contact with the backside BEOL structure 42. Thus, the backside metal structures are used to electrically connect the backside BEOL structure 42 to the backside contact structure 34 which in turn is in conductive contact with the first source/drain region 20 of a transistor. In the illustrated embodiment, the second source/drain region 21 of the transistor is in contact with the frontside BEOL structure 27 through the frontside source/drain contact structure 26.

The backside BEOL structure 42 (which can delivery power from the backside of the device) is composed of an interconnect dielectric region having backside metal wiring embedded therein. The interconnect dielectric region includes one or more interconnect dielectric material layers. The interconnect dielectric material layers can be composed of one of the ILD materials mentioned above. The backside metal wiring, which can be in the form of metal lines, metal vias, metal via/metal line combinations or any combination thereof, is composed of an electrically conductive metal or an electrically conductive metal alloy, as both defined above. The backside BEOL structure 42 can be formed utilizing any well-known BEOL process including a damascene process or a subtractive metal etch process.

In the embodiment illustrated in FIGS. 8A-8B, a portion of the diffusion break structure 22 remains in the isolation region and, as such, the backside contact structure 34 that is present in the first device region, A1, is not connected to, the backside contact structure 34 present in the second device region, A2. Thus, the transistors in the first device region, A1, are not latched to the transistor in the second device region, A2.

Referring now to FIG. 9, there is illustrated a semiconductor device in accordance with another embodiment of the present application. In this embodiment the first device region, A1, is located laterally adjacent to (i.e., in a same row as) second device region, A2. That is, in this embodiment, the second device region, A2 is located to right or left of the first device region, A1, illustrated in the top-down view shown in FIG. 3B. The transistors in the first and second device regions (A1, A2) can be of a same polarity, or of a different polarity. In the illustrated embodiment shown in FIG. 9, and in Region 1, first source/drain region 20 of a transistor in the second device region, A2, shares a backside contact structure 34 with first source/drain region 20 of a transistor in the first device region, A1.

Referring now to FIG. 10, there is illustrated semiconductor device in accordance with a further embodiment of the present application. The semiconductor device illustrated in FIG. 10 is similar to the one illustrated in FIG. 9 in that first source/drain region 20 of a transistor in the second device region, A2, shares a backside contact structure 34 with first source/drain region 20 of a transistor in the first device region, A1. The semiconductor device illustrated in FIG. 10 however differs from the semiconductor device illustrated in FIG. 9 in that it includes a backside source/drain contact structure 44 that contacts first source/drain region 20A of another transistor in the second device region, A2; and no backside contact structure 34 contacts a sidewall of the first source/drain region 20 that is contacted by the backside source/drain contact structure 44; and one diffusion break structure 22 remains intact in the second device region, A2. The backside source/drain contact structure 44 includes at least a contact conductor material as mentioned above for the frontside source/drain contact structure 26. The backside source/drain contact structure 44 can also include a contact liner as mentioned above for the frontside source/drain contact structure 26. The backside source/drain contact structure 44 can be formed by a metallization process as is known to those skilled in the art.

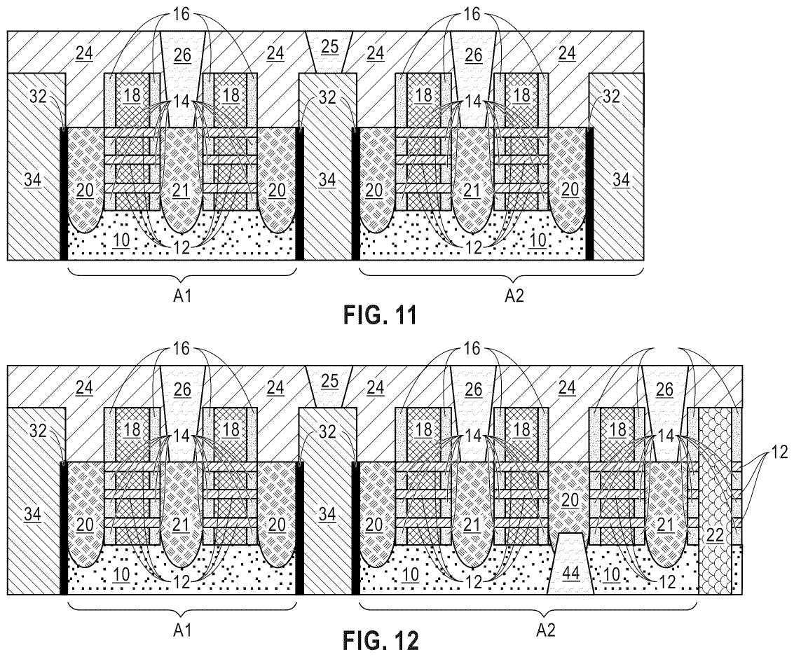

Referring now to FIG. 11, there is illustrated a semiconductor device in accordance with an even further embodiment of the present application. The semiconductor device illustrated in FIG. 11 is similar to the one illustrated in FIG. 9 in that first source/drain region 20 of a transistor in the second device region, A2, shares a backside contact structure 34 with first source/drain region 20 of a transistor in the first device region, A1. The semiconductor device illustrated in FIG. 11, however, differs from the semiconductor device illustrated in FIG. 9 in that it includes a frontside contact structure 25 that contacts a topmost surface of the “shared” backside contact structure 34. The frontside contact structure 25 includes at least a contact conductor material as mentioned above for the frontside source/drain contact structure 26. The frontside contact structure 25 can also include a contact liner as mentioned above for the frontside source/drain contact structure 26. The frontside contact structure 25 can be formed by a metallization process as is known to those skilled in the art.

Referring now to FIG. 12, there is illustrated a semiconductor device in accordance with a still further embodiment of the present application. The semiconductor device illustrated in FIG. 12 is similar to the one illustrated in FIG. 10 except that it contains frontside contact structure 25 (as mentioned above) that contacts a topmost surface of the “shared” backside contact structure 34. The frontside contact structure 25 includes at least a contact conductor material as mentioned above for the frontside source/drain contact structure 26.

Referring now to FIG. 13, there is illustrated a semiconductor device in accordance with yet a further embodiment of the present application. The semiconductor device illustrated in FIG. 13 is similar to the semiconductor device illustrated in FIG. 8B, except that a continuous backside contact structure 34C is present that runs through the first device region, A1, the isolation region, and the second device region, A2. Thus, a transistor in the first device region, A1, is latched to a transistor in the second device region, A2. Also, in this embodiment, the frontside source/drain contact structure 26 is not shared between the transistors that are present in the first device region, A1, and the second device region, A2. In FIG. 8B, frontside source/drain contact structure 26 is shared between the first device region, A1, and the second device region, A2. Notably, and in this embodiment the continuous backside contact structure 34C connects two separate active device areas, e.g., A1 and A2, along two separate rows.

Although not shown in FIGS. 9-12, the exemplary structure illustrated in those drawings can be processed to include a backside ILD layer 36, a backside metal via 39, a backside metal line 40, a backside BEOL structure 42 and a frontside BEOL structure 27 as shown in FIG. 8A.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a backside contact structure located within at least a portion of a diffusion break region that is adjacent to a first device region, wherein a sidewall of the backside contact structure is in conductive contact with a sidewall of a source/drain region of a transistor located in the first device region.

2. The semiconductor device of claim 1, further comprising a second device region separated from the first device region by an isolation region, wherein the diffusion break region spans across the isolation region and is adjacent to the second device region.

3. The semiconductor device of claim 1, further comprising a metal semiconductor alloy contact liner separating the backside contact structure from the source/drain region of the transistor located in the first device region.

4. The semiconductor device of claim 1, further comprising a well region located beneath the transistor located in the first device region, wherein the sidewall of the backside contact structure further contacts the well region.

5. The semiconductor device of claim 1, further comprising a backside source/drain contact structure contacting a source/drain region of another transistor located in the first device region.

6. The semiconductor device of claim 1, further comprising a backside back-end-of-line (BEOL) structure located beneath the transistor and in contact with the backside contact structure.

7. The semiconductor device of claim 1, further comprising a frontside source/drain contact structure in contact with another source/drain region of the transistor located in the first device region.

8. The semiconductor device of claim 7, further comprising a frontside BEOL structure in contact with the frontside source/drain contact structure.

9. The semiconductor device of claim 2, further comprising another backside contact structure having a sidewall in conductive contact with a sidewall of a source/drain region of a transistor located in the second device region, the backside contact structure and the another backside contact structure are located within the diffusion break region and spaced apart by at least a portion of the diffusion break region.

10. The semiconductor device of claim 2, wherein the backside contact structure extends across the isolation region and through at least a portion the diffusion break region and contacts a sidewall of a source/drain region of a transistor in the second device region.

11. A semiconductor device comprising:
a backside contact structure located in at least a portion of a diffusion break region that spans across an isolation region which separates a first device region from a second device region, wherein a first sidewall of the backside contact structure is in conductive contact with a sidewall of a source/drain region of a transistor located in the first device region and a second sidewall of backside contact structure is in conductive contact a sidewall of a source/drain region of a transistor located in the second device region.

12. The semiconductor device of claim 11, wherein the first sidewall of the backside contact structure directly contacts the sidewall of the source/drain region of the transistor located in the first device region, and the second sidewall of the backside contact structure directly contacts the sidewall of the source/drain region of the transistor located in the second device region.

13. The semiconductor device of claim 11, further comprising a metal semiconductor alloy contact liner separating the backside contact structure from the source/drain region of the transistor in the first device region and the source/drain region of the transistor in the second device region.

14. The semiconductor device of claim 11, further comprising a well region located beneath each transistor, wherein the first sidewall and the second sidewall of the backside contact structure further contacts the well region.

15. The semiconductor device of claim 11, further comprising a backside back-end-of-line (BEOL) structure located beneath the transistor located in the first device region and the transistor located in the second device region, wherein the backside BEOL structure is in contact with the backside contact structure.

16. The semiconductor device of claim 11, further comprising a frontside source/drain contact structure in contact with another source/drain region of the transistor located in the first device region, and another frontside source/drain contact structure in contact with another source/drain region of the transistor located in the second device region.

17. The semiconductor device of claim 16, further comprising a frontside BEOL structure in contact with each frontside source/drain contact structure.

18. The semiconductor device of claim 11, further comprising a backside source/drain contact structure contacting a source/drain region of another transistor located in the second device region.

19. The semiconductor device of claim 11, further comprising a frontside contact structure contacting the backside contact structure.

20. The semiconductor device of claim 19, further comprising a backside source/drain contact structure contacting a source/drain region of another transistor located in the second device region.
